(19) United States
(12) Patent Application Publication
(10) Pub. No.: US 2021/0249544 A1
(43) Pub. Date: Aug. 12, 2021

(54) SOLAR CELL AND MANUFACTURING METHOD THEREOF

(71) Applicant: ELECTRONICS AND TELECOMMUNICATIONS RESEARCH INSTITUTE, Daejeon (KR)

(72) Inventors: Sun Jin YUN, Daejeon (KR); Kwang Hoon JUNG, Changwon-si (KR); Sohyun KIM, Daejeon (KR)

(73) Assignee: ELECTRONICS AND TELECOMMUNICATIONS RESEARCH INSTITUTE, Daejeon (KR)

(21) Appl. No.: 17/244,949

(22) Filed: Apr. 29, 2021

Related U.S. Application Data
(63) Continuation of application No. 16/547,055, filed on Aug. 21, 2019.

(30) Foreign Application Priority Data
Sep. 3, 2018 (KR) 10-2018-0104619
Apr. 10, 2019 (KR) 10-2019-0042052

(51) Int. Cl. H01L 31/0224; H01L 31/028; H01L 31/0312; H01L 31/0296; H01L 31/18; H01L 31/0336; H01L 31/0745; H01L 31/073; H01L 31/0749; H01L 31/032

(52) U.S. Cl. CPC H01L 31/022491; H01L 31/022483; H01L 31/028; H01L 31/0312; H01L 31/0296; H01L 31/0322; H01L 31/0336; H01L 31/0745; H01L 31/073; H01L 31/0749; H01L 31/1884

(57) ABSTRACT

Provided are a solar cell and a method of manufacturing the same. The solar cell includes a substrate, a first electrode on the substrate, a second electrode on the first electrode, and at least one semiconductor layer interposed between the first and second electrodes, and a first connection layer interposed between the first electrode and the semiconductor layer and electrically connecting the first and second electrodes to each other. The first connection layer includes a plurality of two-dimensional layers vertically extending from a top surface of the first electrode to a bottom surface of the semiconductor layer. The two-dimensional layers include a metal compound.

### CROSS-REFERENCE TO RELATED APPLICATIONS

This application is a continuation of U.S. application Ser. No. 16/547,055, filed on Aug. 21, 2019, which claims priority under 35 U.S.C. § 119 of Korean Patent Applications No. 10-2018-0104619, filed on Sep. 3, 2018, and 10-2019-0042052, filed on Apr. 10, 2019, the entire contents of which are hereby incorporated by reference.

### BACKGROUND

The present disclosure relates to a solar cell and a method of manufacturing the same, and more particularly, to a thin film solar cell and a method of manufacturing the same.

In relation to a two-dimensional material, since adjacent layers are bonded with van der Waals forces, the layer is easily peeled off. Since each layer of the two-dimensional material is bonded only with adjacent layers through van der Waals attraction forces, carriers are not scattered so that it is known to have high carrier mobility. This is a characteristic that distinguishes it from general thin film type compounds that maintain covalent bonds or metal bonds between layers. Therefore, research and development have been made on transistors utilizing two-dimensional materials having a high carrier mobility.

Photovoltaic generation, which converts light energy into electrical energy using the photovoltaic conversion effect, is widely used as means for obtaining renewable clean energy. Then, with the improvement of the conversion efficiency of solar cells, a photovoltaic generation system using a plurality of solar cell modules is also installed in houses or buildings. A solar cell includes a semiconductor layer having a p-n or p-i-n junction, and generates current using light incident on the semiconductor layer.

### SUMMARY

The present disclosure is to provide a solar cell with improved efficiency.

The present disclosure is also to provide a method of manufacturing a solar cell with improved efficiency.

An embodiment of the inventive concept provides a solar cell including: substrate; a first electrode on the substrate, a second electrode on the first electrode, and at least one semiconductor layer interposed between the first and second electrodes; and a first connection layer interposed between the first electrode and the semiconductor layer and electrically connecting the first and second electrodes to each other, wherein the first connection layer includes a plurality of two-dimensional layers vertically extending from a top surface of the first electrode to a bottom surface of the semiconductor layer, wherein the two-dimensional layers include a metal compound.

In an embodiment of the inventive concept, a method of manufacturing a solar cell includes: forming a first electrode on a substrate;

performing a chalcogenization reaction on the first electrode to form a connection layer; and sequentially forming a semiconductor layer or semiconductor layers and a second electrode on the connection layer, wherein the forming of the connection layer includes reacting a metal on the first electrode with a chalcogen precursor to form a plurality of vertically oriented two dimensional films.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view of a solar cell according to an embodiment of the inventive concept;

FIG. 2 is an enlarged perspective view of one cell of FIG. 1;

FIG. 3 is a cross-sectional view taken along line A-A′ of FIG. 2;

FIGS. 4 and 5 illustrate a method of manufacturing a solar cell according to an embodiment of the inventive concept, and are cross-sectional views taken along line A-A′ in FIG. 2;

FIGS. 6 and 7 illustrate a method of manufacturing a solar cell according to another embodiment of the inventive concept, and are cross-sectional views taken along line A-A′ in FIG. 2;

FIG. 8 illustrates a solar cell according to another embodiment of the inventive concept and is a cross-sectional view taken along line A-A′ of FIG. 2; and

FIGS. 9 and 10 are perspective views of a solar cell according to a further another embodiment of the inventive concept.

### DETAILED DESCRIPTION

In order to fully understand the configuration and effects of the technical spirit of the inventive concept, preferred embodiments of the technical spirit of the inventive concept will be described with reference to the accompanying drawings. However, the technical spirit of the inventive concept is not limited to the embodiments set forth herein and may be implemented in various forms and various modifications may be applied thereto. Only, the technical spirit of the inventive concept is disclosed to the full through the description of the embodiments, and it is provided to those skilled in the art that the inventive concept belongs to inform the scope of the inventive concept completely.

It will also be understood that when a layer (or film) is referred to as being ‘on’ another layer or substrate, it may be directly on the other layer or substrate, or intervening layers may also be present. Additionally, in the drawings, the thicknesses of components are exaggerated for effective description. Like reference numerals refer to like elements throughout the specification.

It will be understood that the terms “first” and “second” are used herein to describe various components but these components should not be limited by these terms. These terms are just used to distinguish a component from another component. Embodiments described herein include complementary embodiments thereof

The terms used in this specification are used only for explaining specific embodiments while not limiting the inventive concept. The terms of a singular form may include plural forms unless referred to the contrary. The meaning of “comprises,” and/or “comprising” in this specification specifies the mentioned component but does not exclude at least one another component

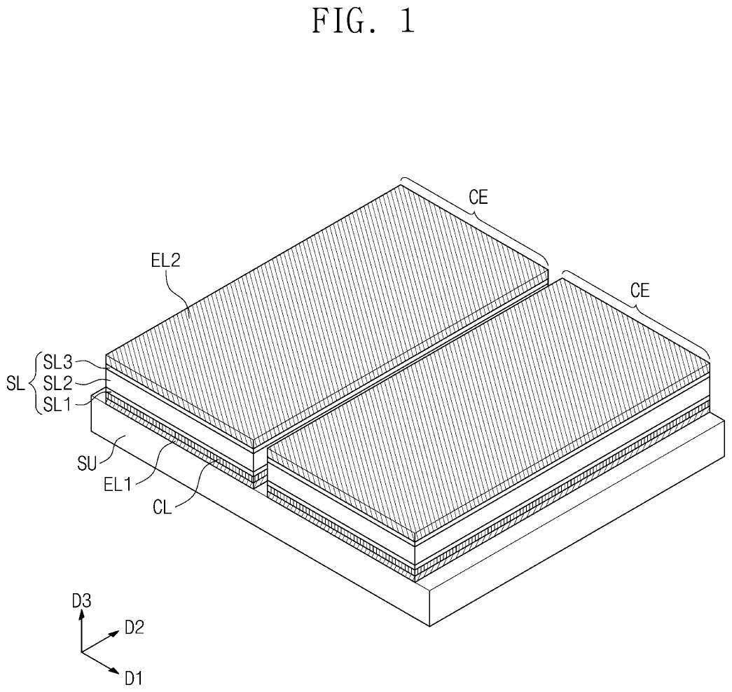

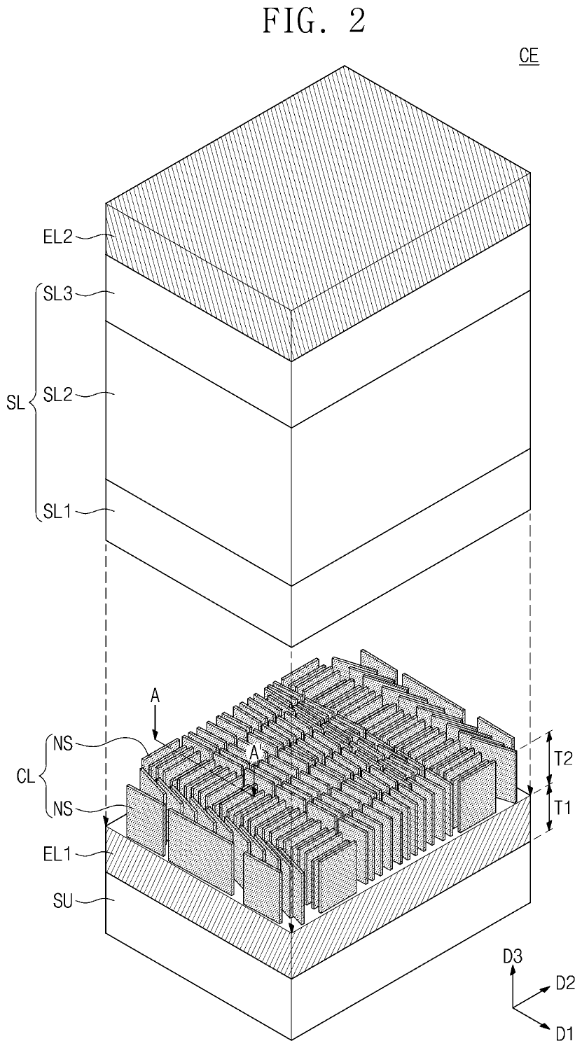

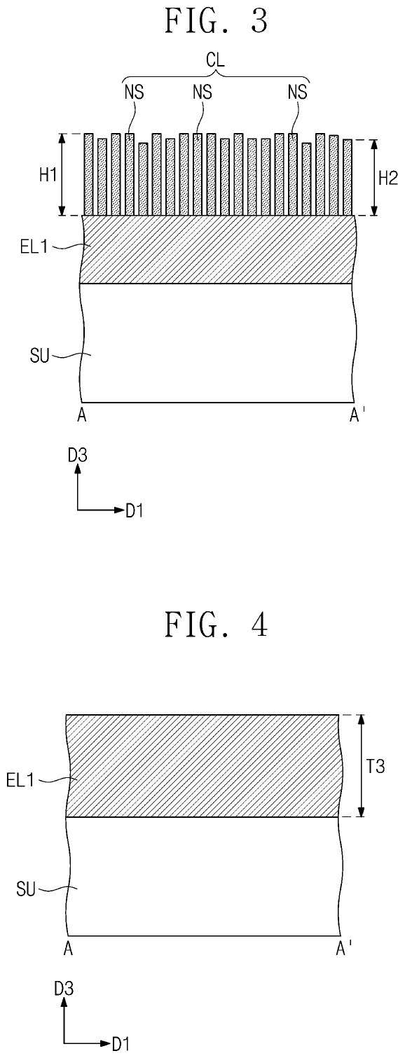

FIG. 1 is a perspective view of a solar cell according to an embodiment of the inventive concept. FIG. 2 is an enlarged perspective view of one cell of FIG. 1. FIG. 3 is a cross-sectional view taken along line A-A′ of FIG. 2.

Referring to FIGS. 1 to 3, a plurality of cells CE may be provided on a substrate SU. The plurality of cells CE may be connected to each other to constitute a solar cell according to the inventive concept. The cells CE may have a line shape extending in a second direction D2. The cells CE may be arranged in a first direction D1. The plurality of cells CE may be connected to each other in series or in parallel.

As an example, the substrate SU may include a silicon oxide layer, stainless steel, plastic, or glass.

Each of the cells CE may include a first electrode EL1, a connection layer CL, one or more semiconductor layers SL, and a second electrode EL2 which are sequentially stacked. The connection layer CL is interposed between the first electrode EL1 and the semiconductor layer SL so that it may electrically connect them.

The semiconductor layer SL may include a first semiconductor layer SL1, a second semiconductor layer SL2, and a third semiconductor layer SL3. The second semiconductor layer SL2 may be interposed between the first and third semiconductor layers SL1 and SL3. The first semiconductor layer SL1 may contact the connection layer CL. In other words, the bottom surface of the first semiconductor layer SL1 may contact the top surface of the connection layer CL.

The first semiconductor layer SL1 may have a first conductivity type and the third semiconductor layer SL3 may have a second conductivity type different from the first conductivity type. For example, the first conductivity type may be N-type, and the second conductivity type may be P-type. As another example, the first conductivity type may be P-type, and the second conductivity type may be N-type. The second semiconductor layer SL2 may be an intrinsic semiconductor. As another example, the second semiconductor layer SL2 may be one of N-type or P-type semiconductors. The second semiconductor layer SL2 may function as a light absorbing layer. The thickness of the second semiconductor layer SL2 may be greater than the thickness of the first semiconductor layer SL1. The thickness of the second semiconductor layer SL2 may be greater than the thickness of the third semiconductor layer SL3. The thickness of the second semiconductor layer SL2 may be 100 nm to 3,000 nm. More specifically, the thickness of the second semiconductor layer SL2 may be 100 nm to 400 nm. As one example, the first to third semiconductor layers SL1, SL2, and SL3 may include silicon, germanium, silicon-germanium, silicon oxide, or silicon carbide. The first to third semiconductor layers SL1, SL2, SL3 may be amorphous or microcrystalline. Here ‘microcrystalline’ comprises the meanings of ‘nano-crystalline’ and ‘polycrystalline’.

The second electrode EL2 may be provided on the top surface of the third semiconductor layer SL3. As an example, the second electrode EL2 may be formed of any one of indium zinc oxide (IZO), indium tin oxide (ITO), indium gallium oxide (IGO), indium zinc gallium oxide (IGZO), titanium zinc oxide (TZO), gallium-doped zinc oxide (GZO), aluminum doped zinc oxide (AZO), and a combination thereof. As an example, the second electrode EL2 may be one of transparent conducting layers. The second electrode EL2 may be composed of multilayers. As another example, the second electrode EL2 may include W, Mo, Ti, Ag, Cu, Al, Ni, or an alloy thereof.

Referring again to FIG. 2 and FIG. 3, the first electrode EL1 and the connection layer CL will be described in more detail. The connection layer CL may include a plurality of two-dimensional layers NS. The crystal direction of the two-dimensional layers NS may be oriented in a third direction D3 perpendicular to the top surface of the substrate SU. The two-dimensional layers NS may extend in the third direction D3 from the top surface of the first electrode EL1 to the bottom surface of the first semiconductor layer SL1. From a plan viewpoint, the two-dimensional layers NS may be randomly arranged. That is, the two-dimensional layers NS may have a vertical orientation with respect to the substrate SU, and a first two-dimensional layer may extend in the first direction D1 and the second two-dimensional layer may extend in the second direction D2. The first direction D1 and the second direction D2 may intersect with each other.

Each of the two-dimensional layers NS may include a metal chalcogenide. Each of the two-dimensional layers NS may include a transition metal chalcogenide. In other words, each of the two-dimensional layers NS may include a metal compound represented by the formula MxXy (in one embodiment, x and y is an integer of 1, 2 or 3). In the above formulas, M is a metal or a transition metal atom and may include, for example, W, Mo, Ti, V, Zn, Hf or Zr. X is a chalcogen atom and may include, for example, S, Se, O or Te. Each of the two-dimensional layers NS may include one selected from the group consisting of MoS₂, MoSe₂, MoTe₂, WS₂, WSe₂, WTe₂, ReS₂, ReSe₂, TiS₂, TiSe₂, TiTe₂, VO₂, VS₂, VSe₂, ZnO, ZnS₂,

ZnSe₂, HfS₂, HfSe₂, WO₃, and MoO₃.

The two-dimensional layers NS may have semiconductor properties. The two-dimensional layers NS may include a metal compound having the same first conductivity type as the first semiconductor layer SL1. For example, when the first semiconductor layer SL1 has an N-type, the two-dimensional layers NS may include N-type MoS₂, MoSe₂, WS₂, ZnS₂, ZnSe₂, HfS₂, HfSe₂, ReSe₂, or ReS₂. In another example, when the first semiconductor layer SL1 has a P-type, the two-dimensional layers NS may include P-type WSe₂, Graphene oxide, or VO₂. As another example, the two-dimensional layers NS may have conductor properties. That is, the band gap energy of the two-dimensional layers NS which are conductors may be substantially 0 eV. Two-dimensional materials with a band gap energy of 0 eV may include TiS₂, TiSe₂, VS₂, or VSe₂.

Each of the two-dimensional layers NS may have a monolayer structure having a strong bonding force between the constituent atoms.

Alternatively, each of the two-dimensional layers NS may have a structure in which monolayers are stacked in a direction parallel to the top surface of the first electrode EL1. Each of the two-dimensional layers NS may have the structure in which monolayers are formed in a direction normal to the top surface of the first electrode EL1. Here, adjacent monolayers may be bonded together with a very weak van der

Waals attraction. In other words, the two-dimensional layer NS may be collectively referred to as a layer having the above-described two-dimensional structure. As an example, the two-dimensional layer NS may have a monolayer of a metal chalcogenide or a transition metal chalcogenide. Here, the monolayer means one layer having the formula of MX₂ when metal decalcogenide is used as an example.

Referring again to FIG. 3, the two-dimensional layers NS adjacent to each other may be bonded to each other by a van der Waals force. For example, the first two-dimensional layer NS and the second two-dimensional layer NS adjacent thereto in the first direction D1 may be bonded to each other by a van der Waals force parallel to the first direction D1. The two-dimensional layers NS may have different heights. For example, one of the two-dimensional layers NS may have a first height H1 and the other two-dimensional layer NS may have a second height H2. At this time, the first height H1 and the second height H2 may be different from each other.

The two-dimensional layers NS may include the same material. In other words, the two-dimensional layers NS may have the same composition with each other. The two-dimensional layers NS may have a single crystal structure or a polycrystalline structure. Each of the two-dimensional layers NS may have a crystal structure oriented in the third direction D3. The two-dimensional layers NS may have the same crystal structure or different crystal structures. For example, the crystal structure may include a hexagonal lattice structure, a cubic structure, a triangular lattice structure, an orthorhombic lattice structure, and a modified tetragonal (monoclinic) lattice structure.

In one embodiment, the first electrode EL1 may include the same metal as the two-dimensional layers NS. When the two-dimensional layers NS include a metal compound of MxX_{y}, the first electrode EL1 may include M metal. In one example, when the two-dimensional layers NS include MoS₂, the first electrode EL1 may include Mo. This is because, when the connection layer CL is formed, the first electrode EL1 serves as a precursor layer of the connection layer CL. The relative thickness of metal and metal compounds may be adjusted by adjusting the temperature and time in the manufacturing process.

In another embodiment, the first electrode EL1 may include a metal different from the metal constituting the two-dimensional layers NS. The first electrode EL1 may be a transparent conductor. Specifically, the first electrode EL1 may include a transparent conducting layer. The transparent conducting layer may include Indium tin oxide (ITO), tin oxide (SnO), F-doped tin oxide (FTO), Zinc oxide (ZnO), Titanium dioxide (TiO₂), Ga-doped zinc oxide (GZO), or Al-doped zinc oxide (AZO). When the first electrode EL1 is a transparent electrode including a transparent conducting layer, the second electrode EL2 may also be formed as a transparent electrode including a transparent conducting layer to form transparent devices such as transparent solar cells.

The first electrode EL1 may have a first thickness T1 and the connection layer CL may have a second thickness T2. The first thickness T1 may be 5 nm to 900 nm. More specifically, the first thickness T1 may be 5 nm to 100 nm.

The second thickness T2 may be 15 nm to 100 nm. More specifically, the second thickness T2 may be 15 nm to 30 nm. In one example, the first thickness T1 may be greater than the second thickness T2.

The solar cell according to embodiments of the inventive concept may include a connection layer CL composed of vertically oriented two-dimensional layers NS. A current may flow between the first electrode EL1 and the semiconductor layer SL through the two-dimensional layers NS of the connection layer CL. Since the two-dimensional layers NS extend in the third direction D3 from the top surface of the first electrode EL1 to the bottom surface of the semiconductor layer SL, the current flows through the two-dimensional layers NS in the third direction D3.

Solar cells are often required to be used in low-light environments (i.e., low light intensity environments). In general, the efficiency of the solar cell is greatly reduced under low light conditions. The reason for the decrease in the efficiency at low light intensity is that the influence of the leakage current becomes large under the low light condition in which the amount of photo-carrier generation is small. The leakage current is related to the shunt resistance. If the shunt resistance is large, the leakage current becomes small. Conversely, if the shunt resistance is small, the leakage current becomes large.

The two-dimensional layers NS may be horizontally spaced from each other. For example, the two-dimensional layers NS may be spaced from each other in the first direction D1 (see FIG. 3). The separation refers to a condition that layers may be easily separated because they are combined with a simple physical force such as the van der Waals force. In such a way, the charged carrier flow is interrupted between the layers bonded by the van der Waals force. Therefore, the current flowing through the connection layer CL hardly flows in a direction (e.g., the first direction D1 or the second direction D2) parallel to the top surface of the substrate SU. In other words, the connection layer CL may induce a relatively large shunt resistance. As a result, the solar cell according to the inventive concept may prevent leakage current from occurring. The solar cell according to the inventive concept may provide excellent efficiency under low light conditions.

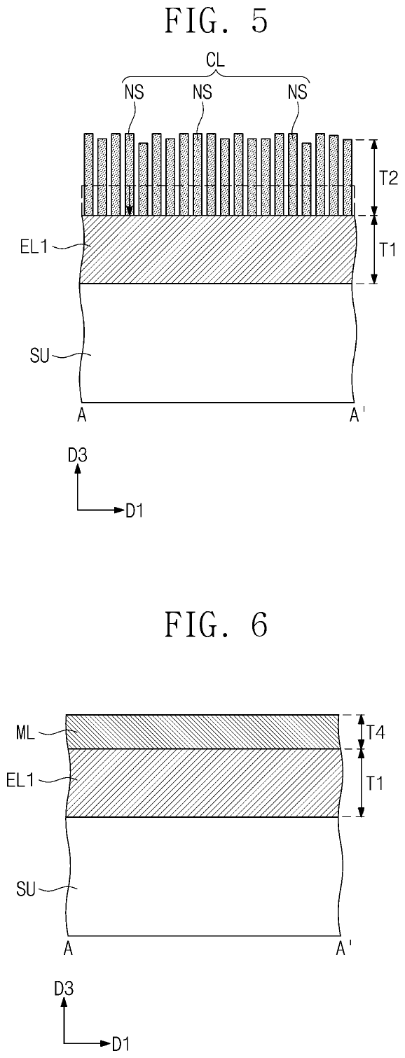

FIGS. 4 and 5 illustrate a method of manufacturing a solar cell according to an embodiment of the inventive concept, and are cross-sectional views taken along line A-A′ in FIG. 2.

Referring to FIG. 4, a first electrode EL1 may be formed on a substrate SU. The first electrode EL1 may be formed with a third thickness T3. The first electrode EL1 may include a metal M. For example, M may include W, Mo, Ti, V, Zn, Hf, or Zr.

Referring to FIG. 5, a connection layer CL may be formed on the first electrode EL1. The connection layer CL may be formed using a chalcogenization reaction in which a part of the first electrode EU is cholcogenized. Alternatively, the connection layer CL may be formed through chalcogenization reaction of a metal layer formed on the first electrode EL1.

The chalcogenation reaction may include providing a precursor of chalcogen X on the top surface of the first electrode EL1 or on the top surface of the metal layer deposited on the first electrode EL1. For example, X may include S, Se, O, or Te. The chalcogenation reaction may be performed at a temperature of 300° C. to 1000° C. More precisely, the chalcogenation reaction may be performed at a temperature of 300° C. to 530° C.

The metal M of the first electrode EL1 and the chalcogen X of the precursor react with each other to form a plurality of two-dimensional layers NS. The two-dimensional layers NS may be grown in the vertical direction (i.e., the third direction D3) from the top surface of the first electrode EL1.

When the third thickness T3 of the first electrode EL1 is sufficiently thick, the two-dimensional layers NS may be grown in the third direction D3. As an example, the third thickness T3 may be 5 nm to 1,000 nm. More precisely, the third thickness T3 may be 50 nm to 1,000 nm.

The thickness of the first electrode EL1 is reduced while the two-dimensional layers NS are formed so that the first electrode EL1 may have a first thickness T1. The first thickness T1 may be smaller than the third thickness T3. The connection layer CL may be formed with a second thickness T2. As the process temperature and reaction time of the chalcogenide reaction increase, the second thickness T2 of the connection layer CL may increase. In other words, as the process temperature and reaction time of the chalcogenization reaction increase, the height of the two-dimensional layers NS (i.e., H1 and H2 in FIG. 3) may increase. By controlling the process temperature and reaction time of the chalcogenization reaction, the thickness T2 of the connection layer CL may be adjusted.

Referring again to FIGS. 1 to 3, the semiconductor layer SL may be formed on the connection layer CL. The formation of the semiconductor layer SL may include sequentially forming the first semiconductor layer SL1, the second semiconductor layer SL2 and the third semiconductor layer SL3 on the connection layer CL. The second electrode EL2 may be formed on the semiconductor layer SL. As a laminated structure including a first electrode EL1, a connection layer CL, a semiconductor layer SL and a second electrode EL2 is patterned, a plurality of cells CE may be formed.

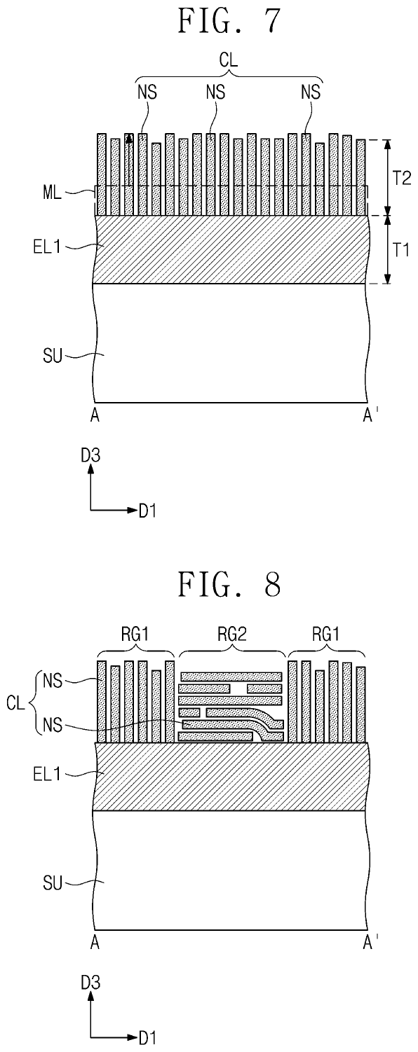

FIGS. 6 and 7 illustrate a method of manufacturing a solar cell according to another embodiment of the inventive concept, and are cross-sectional views taken along line A-A′ in FIG. 2. In this embodiment, the detailed description of the technical features overlapping with those described with reference to FIGS. 4 to 5 will be omitted, and the differences will be described in detail.

Referring to FIG. 6, a first electrode EL1 may be formed on a substrate SU. The first electrode EL1 may be formed with a first thickness T1. Specifically, the first electrode EL1 may include a transparent conducting layer.

A metal layer ML may be formed on the first electrode EL1. The metal layer ML may include a metal M. For example, M may include W, Mo, Ti, V, Zn, Hf, or Zr. The metal layer ML may have a fourth thickness T4. The fourth thickness T4 may be 5 nm to 100 nm. More specifically, the fourth thickness T4 may be 5 nm to 10 nm.

Referring to FIG. 7, a connection layer CL may be formed from the metal layer ML. In other words, the metal layer ML may be converted into the connection layer CL. As the connection layer CL is formed from the metal layer ML, the connection layer CL may be located on the first electrode EL1. The connection layer CL may be formed using a chalcogenization reaction using a metal layer ML as a precursor layer. The chalcogenization reaction may be performed until some or all of the metal layer ML is reacted. The chalcogenization reaction may be performed by providing a chalcogen precursor including S, Se, O or Te on the metal layer ML.

Referring again to FIGS. 1 to 3, the semiconductor layer SL may be formed on the connection layer CL. The second electrode EL2 may be formed on the semiconductor layer SL. For example, the second electrode EL2 may also include a transparent conducting layer. As a laminated structure including a first electrode EL1, a connection layer CL, a semiconductor layer SL and a second electrode EL2 is patterned, a plurality of cells CE may be formed.

When the first electrode EL1 and the second electrode EL2 are formed of a transparent electrode including a transparent conductive oxide or an oxide-very thin metal-oxide (OMO) transparent layer, a transparent solar cell including a connection layer that transmits a part of sunlight may be formed.

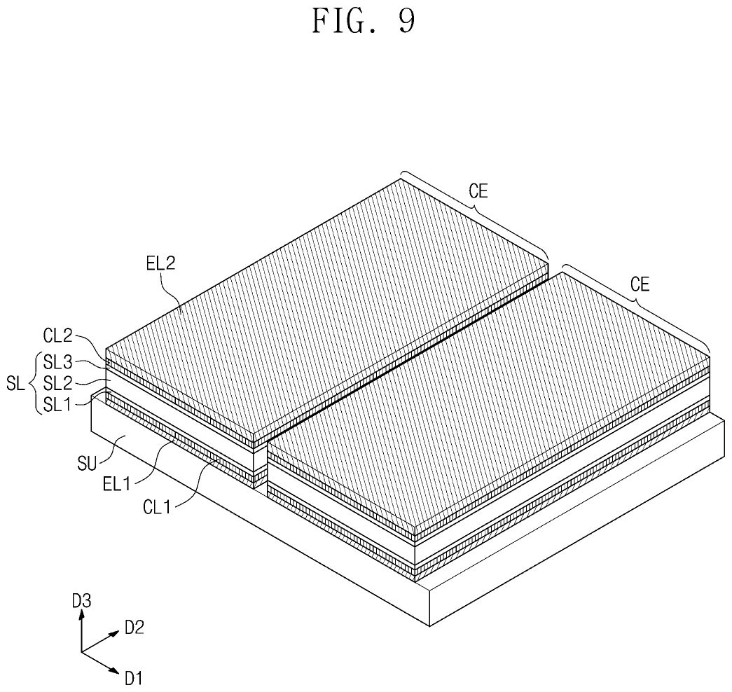

FIG. 8 illustrates a solar cell according to another embodiment of the inventive concept and is a cross-sectional view taken along line A-A′ of FIG. 2. In this embodiment, the detailed description of the technical features overlapping with those described with reference to FIGS. 1 to 3 will be omitted, and the differences will be described in detail.

Referring to FIGS. 1, 2 and 8, the connection layer CL may include a first region RG1 and a second region RG2. The first region RG1 may include vertically oriented two-dimensional layers NS and the second region RG2 may include horizontally oriented two-dimensional layers NS. For example, the two-dimensional layers NS of the first region RG1 may extend in the third direction D3 from the top surface of the first electrode EL1. The two-dimensional layers NS of the second region RG2 may extend in a first direction D1 which is a direction parallel to the top surface of the first electrode EL1. The two-dimensional layers NS of the second region RG2 may be stacked in the third direction D3.

Since the two-dimensional layers NS are horizontally oriented in the second region RG2, current may flow in a direction parallel to the top surface of the substrate SU in the second region RG2. As an example, the second region RG2 may be surrounded by the first region RG1. The first region RG1 surrounding the second region RG2 may prevent the current from flowing horizontally. As a result, the solar cell according to the present embodiment may prevent leakage current from occurring.

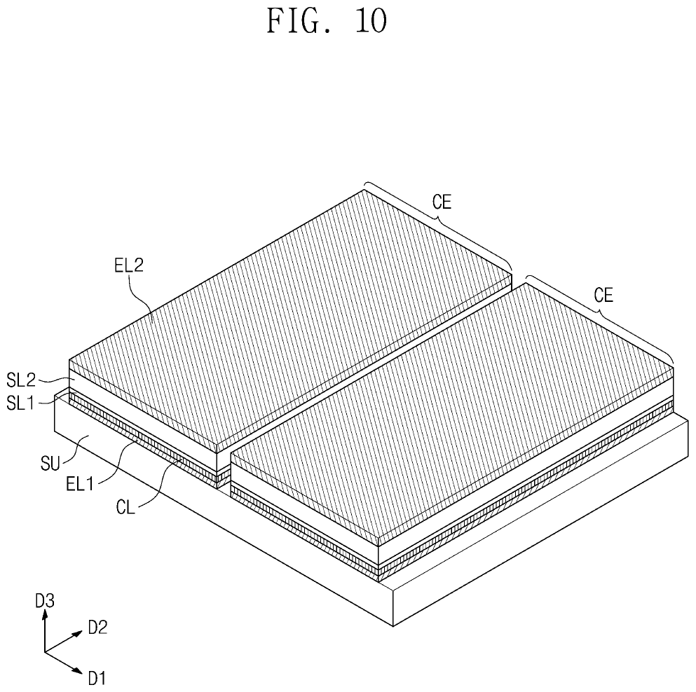

FIG. 9 is a perspective view of a solar cell according to a further another embodiment of the inventive concept. In this embodiment, the detailed description of the technical features overlapping with those described with reference to FIGS. 1 to 3 will be omitted, and the differences will be described in detail.

Referring to FIG. 9, each of the cells CE includes a first electrode EL1, a first connection layer CL1, a semiconductor layer SL, a second connection layer CL2, and a second electrode EL2 which are sequentially stacked. The first connection layer CL1 is interposed between the first electrode EL1 and the first semiconductor layer SL1 so that it may electrically connect them. The second connection layer CL2 is interposed between the second electrode EL2 and the third semiconductor layer SL3 so that it may electrically connect them.

The first connection layer CL1 may include a metal compound having the same first conductivity type as the first semiconductor layer SL1. The second connection layer CL2 may include a metal compound having the same second conductivity type as the third semiconductor layer SL3. The connection layers CL1 and CL2 may include a metal compound which is a conductor.

Each of the first and second connection layers CL1 and CL2 may include a plurality of vertically oriented two-dimensional layers. A detailed description of the two-dimensional layers of the first and second connection layers CL1 and CL2 may be the same as that described with reference to FIGS. 2 and 3 above. For example, the two-dimensional layers of the second connection layer CL2 may extend in the third direction D3 from the top surface of the third semiconductor layer SL3 to the bottom surface of the second electrode EL2.

The second electrode EL2 may include the same metal as the second connection layer CL2. When the second connection layer CL2 includes a metal compound of MxX_{y}, the second electrode EL2 may include M metal. For example, when the second connection layer CL2 includes WSe₂ two-dimensional layers, the second electrode EL2 may include W.

FIG. 10 is a perspective view of a solar cell according to further another embodiment of the inventive concept. In this embodiment, the detailed description of the technical features overlapping with those described with reference to FIGS. 1 to 3 will be omitted, and the differences will be described in detail.

Referring to FIG. 10, each of the cells CE includes a first electrode EL1, a connection layer CL, a first semiconductor layer SL1, a second semiconductor layer SL2, and a second electrode EL2 which are sequentially stacked.

The first semiconductor layer SL1 may be a light absorbing layer. The first semiconductor layer SL1 may include a compound semiconductor. In one example, the first semiconductor layer SL1 may include CuInGaSe(CIGS), CuInSe(CIS), or CdTe. The second semiconductor layer SL2 may be a semiconductor layer having a conductivity type different from that of the first semiconductor layer SL1. The second semiconductor layer SL2 may include a compound semiconductor, for example, any one or more of CdS, ZnO, and ZnS.

As described with reference to FIGS. 1 to 3, the connection layer CL may include vertically oriented two-dimensional layers NS. The two-dimensional layers NS may extend in the third direction D3 from the top surface of the first electrode EL1 to the bottom surface of the first semiconductor layer SL1. The first electrode EL1 and the first semiconductor layer SL1 may be electrically connected through the two-dimensional layers NS. The two-dimensional layers NS of the connection layer CL may prevent current leakage between the first electrode EL1 and the first semiconductor layer SL1.

Embodiment 1

A Mo layer was deposited with a thickness of 100 nm on a SiO₂/Si substrate. A MoS₂ layer was formed by performing a sulfurization reaction of the Mo layer. The process temperature of the sulfurization reaction was maintained at about 350° C. to about 500° C. When the reaction temperature was 500° C., the MoS₂ layer was formed with a thickness of 15 nm. As a result, the TEM analysis of the formed MoS₂ layer confirmed that the MoS₂ two-dimensional layers were oriented vertically. An N-type Si layer of 10 nm, an intrinsic Si layer of 300 nm, and a P-type Si layer of 10 nm were sequentially formed on the MoS₂ layer. A Ga-doped ZnO (GZO) transparent electrode was formed on the P-type Si layer.

Embodiment 2

A solar cell was manufactured in the same manner as in embodiment 1, except that the process temperature of the sulfurization reaction was maintained at about 700° C. At this time, the MoS₂ layer was formed with a thickness of 90 nm.

Embodiment 3

A Mo layer was deposited with a thickness of 100 nm on a SiO₂/Si substrate. A MoSe₂ layer was formed by performing a selenization reaction on the Mo layer. The process temperature of the selenization reaction was maintained at about 350° C. to about 500° C. When the reaction temperature was 500° C., the MoSe₂ layer was formed with a thickness of 15 nm. Thereafter, a solar cell was manufactured in the same manner as in embodiment 1.

Comparative Example 1

A solar cell was manufactured in the same manner as in Example 1, except that the MoS₂ layer was not formed on the Mo layer. In other words, in the solar cell of comparative example 1, the MoS₂ layer of embodiment 1 is omitted.

Experimental Example 1

The open circuit voltage V_{OC}, the short circuit current density J_{SC}, the fill factor FF, the efficiency, the shunt resistance and the series resistance were measured for the solar cell of embodiment 1 and the solar cell of comparative example 1, and their results are shown in Table 1 below. The intensity of light was adjusted to 100 mW/cm².

TABLE 1

| | | | | | Shunt | Serial |
|---|---|---|---|---|---|---|
| | V_{OC} | J_{SC} | FF | efficiency | resistance | resistance |
| | (V) | (mA/cm²) | (%) | (%) | (Ω) | (Ω) |
| Embodiment | 0.831 | 11.0 | 54.2 | 4.95 | 4600 | 81 |
| 1 | | | | | | |
| Comparative | 0.789 | 10.42 | 40.1 | 3.30 | 1500 | 190 |
| example 1 | | | | | | |

Referring to Table 1, in relation to the solar cell according to embodiment 1, V_{OC}, J_{SC}, FF and efficiency are all increased as compared with the solar cell according to comparative example 1. In relation to the solar cell according to embodiment 1, the shunt resistance was increased about 3 times and the series resistance was reduced to about ⅖ as compared with the solar cell of comparative example 1. Due to this, FF and efficiency increased greatly.

Experimental Example 2

By varying the intensity of light irradiated to the solar cell of embodiment 1, their results are shown in Table 2 below.

TABLE 2

| | | | | | Shunt |
|---|---|---|---|---|---|
| Light | V_{OC} | J_{SC} | FF | Efficiency | resistance |
| intensity | (V) | (mA/cm²) | (%) | (%) | (Ω) |
| 100 mW/cm² | 0.831 | 11.0 | 54.2 | 4.95 | 4600 |
| 90 mW/cm² | 0.829 | 9.98 | 54.9 | 5.05 | 4900 |
| 80 mW/cm² | 0.828 | 8.86 | 55.6 | 5.10 | 5900 |
| 70 mW/cm² | 0.827 | 7.87 | 56.3 | 5.24 | 6700 |
| 60 mW/cm² | 0.824 | 6.77 | 57.0 | 5.30 | 8200 |
| 50 mW/cm² | 0.822 | 5.65 | 58.0 | 5.39 | 9000 |
| 40 mW/cm² | 0.818 | 4.50 | 58.8 | 5.41 | 12000 |
| 30 mW/cm² | 0.812 | 3.37 | 59.7 | 5.45 | 14000 |
| 20 mW/cm² | 0.804 | 2.33 | 60.3 | 5.65 | 18000 |

Referring to Table 2, it may be confirmed that the shunt resistance increases as the light intensity decreases. In particular, when the light intensity is 20 mW/cm², the shunt resistance is 18000 Ω and the efficiency is 5.65%, so that it may be confirmed that the solar cell has excellent electrical characteristics. As a result, it may be confirmed that the solar cell according to the embodiment of the inventive concept shows excellent performance under low light conditions.

Experimental Example 3

The open circuit voltage V_{OC}, the short circuit current density J_{SC}, the fill factor FF, the efficiency, the shunt resistance and the series resistance were measured for the solar cell of embodiment 3 and the solar cell of comparative example 1, and their results are shown in Table 3 below. The intensity of light was adjusted to 100 mW/cm².

TABLE 3

| | | | | | Shunt | Serial |
|---|---|---|---|---|---|---|
| | V_{OC} | J_{SC} | FF | Efficiency | resistance | resistance |
| | (V) | (mA/cm²) | (%) | (%) | (Ω) | (Ω) |
| Embodiment | 0.777 | 11.61 | 62.7 | 5.65 | 5500 | 46 |
| 3 | | | | | | |
| Comparative | 0.718 | 9.90 | 42.5 | 3.02 | 2900 | 170 |
| example 1 | | | | | | |

Referring to Table 3, in relation to the solar cell according to embodiment 3, it may be confirmed that a shunt resistance was increased and a series resistance was decreased as compared with the solar cell according to comparative example 1.

As another embodiment of the inventive concept, when a transparent solar cell having a transmittance of 26% was manufactured by depositing the Mo metal on the transparent first electrode on the transparent substrate and setting the reaction temperature to 500° C. to form a 20 nm MoSe₂ layer, under light irradiation conditions of 7 MW/cm², shunt resistances of 32000 Ω and 7.7% may be obtained with greatly improved efficiency.

The metal compound, which is a two-dimensional material presented several times, may be MₐX_{b} (a positive integer excluding a, b=0) (M: metal; X: chalcogen element).

The solar cell according to the inventive concept may have a relatively large shunt (parallel) resistance using vertically oriented two-dimensional layers. As a result, leakage current may be prevented from occurring. Furthermore, the solar cell according to the inventive concept may provide excellent efficiency under low light conditions.

Although the exemplary embodiments of the inventive concept have been described, it is understood that the inventive concept should not be limited to these exemplary embodiments but various changes and modifications may be made by one ordinary skilled in the art within the spirit and scope of the inventive concept as hereinafter claimed.

What is claimed is:

1. A method of manufacturing a solar cell, the method comprising:
forming a first electrode on a substrate;
performing a chalcogenization reaction on the first electrode to form a connection layer; and
sequentially forming a semiconductor layer and a second electrode on the connection layer,
wherein forming the connection layer comprises reacting a metal on the first electrode with a chalcogen precursor to form a plurality of vertically oriented two-dimensional layers.

2. The method of claim 1, wherein at least one region of the two-dimensional layers is grown vertically from a top surface of the first electrode.

3. The method of claim 2, wherein the two-dimensional layers are configured to prevent leakage current in a horizontal direction within the connection layer, the horizontal direction being parallel to the top surface of the first electrode.

4. The method of claim 1, wherein the metal is contained in the first electrode, and
while forming the connection layer, a thickness of the first electrode decreases.

5. The method of claim 4, wherein before forming the connection layer, the thickness of the first electrode is 50 nm to 1,000 nm.

6. The method of claim 4, wherein the first electrode contains the metal selected from the group consisting of W, Mo, Ti, V, Zn, Hf and Zr.

7. The method of claim 1, wherein the metal includes a metal layer formed on the first electrode, and
while forming the connection layer, the metal layer is converted into the connection layer.

8. The method of claim 7, wherein the thickness of the metal layer is 5 nm to 10 nm.

9. The method of claim 7, wherein the metal layer contains W, Mo, Ti, V, Zn, Hf or Zr.

10. The method of claim 1, wherein at least one of the two-dimensional layers has a structure in which monolayers are bonded to each other by van der Waals attraction.

11. The method of claim 1, wherein forming the semiconductor layer comprises forming a first semiconductor layer on the connection layer and a second semiconductor layer on the first semiconductor layer,
wherein the first semiconductor layer has a first conductivity type,
the second semiconductor layer has a second conductivity type different from the first conductivity type, and
the two-dimensional layers have the first conductivity type.

12. The method of claim 1, further comprising controlling a process temperature of the chalcogenization reaction to adjust a thickness of the connection layer.

13. The method of claim 12, wherein the process temperature of the chalcogenation reaction is 300° C. to 530° C.

14. The method of claim 1, wherein the chalcogen precursor includes a chalcogen element selected from the group consisting of S, Se, O and Te.
